(19) United States
(12) Patent Application Publication
(10) Pub. No.: US 2019/0275600 A1
(43) Pub. Date: Sep. 12, 2019

(54) FLUX TRANSFER TOOL AND FLUX TRANSFER METHOD

(71) Applicant: POWERTECH TECHNOLOGY INC., Hsinchu County (TW)

(72) Inventors: Kun-Chi Hsu, Hsinchu County (TW); Sheng-Tou Tseng, Hsinchu County (TW); Hung-Chieh Huang, Hsinchu County (TW)

(21) Appl. No.: 15/915,003

(22) Filed: Mar. 7, 2018

(51) Int. Cl. B23K 1/20; H05K 1/14; H01L 21/56; H05K 3/34; H01L 21/48; H01L 23/13; H01L 23/492; H01L 23/00

(52) U.S. Cl. CPC B23K 1/203; H05K 1/148; H01L 21/563; H05K 3/3489; B23K 2201/40; H01L 21/4871; H01L 23/13; H01L 23/4926; H01L 24/10; H05K 3/3436

(57) ABSTRACT

A flux transfer tool includes a flux tray, a baseplate, a flux transfer head and a flexible member. The baseplate is disposed on the flux tray. The baseplate has a plurality of holes formed thereon. The flux transfer head is arranged corresponding to the flux tray and configured to move with respect to the flux tray. The flexible member is disposed on the flux transfer head. The flexible member faces the baseplate when the flux transfer head is located above the flux tray. When the holes are filled with a flux, the flux transfer head moves towards the flux tray, such that the flexible member adsorbs the flux from the holes.

### BACKGROUND OF THE INVENTION

### 1. Field of the Invention

The invention relates to a flux transfer tool and a flux transfer method and, more particularly, to a flux transfer tool and a flux transfer method for improving a flux transfer process of a ball grid array (BGA) package and Chip Scale Package (CSP).

### 2. Description of the Prior Art

BGA and CSP techniques have become more common in recent years for connecting high-density IC components onto circuit boards. In BGA and CSP techniques, a flux transfer tool is used to transfer flux to a plurality of bond pads of a substrate to remove oxidized film and to provisionally fix solder balls before the solder balls are mounted on the bond pads by a reflow process.

Referring to FIGS. 1 to 3, FIG. 1 is a side view illustrating a flux transfer tool 1 of the prior art, FIG. 2 is a side view illustrating the flux transfer pins 10 adhered with the flux 12, and FIG. 3 is a side view illustrating the flux 12 transferred from the flux transfer pins 10 to the bond pads 20 of the substrate 2. As shown in FIG. 1, the flux transfer tool 1 comprises a plurality of flux transfer pins 10. A flux 12 in a flux tray 14 is extended to a uniform thickness by means of a scraper 16. Then, the flux transfer tool 1 is driven to move towards the flux tray 14, such that the flux 12 adheres to each of the flux transfer pins 10 uniformly, as shown in FIG. 2. Then, the flux transfer tool 1 is driven to move to a position above a substrate 2 and move towards the substrate 2, such that the flux 12 is transferred from the flux transfer pins 10 to a plurality of bond pads 20 of the substrate 2, as shown in FIG. 3.

As demand for electronic devices that are smaller and more powerful continues to increase, the size of the solder ball and the pitch between two adjacent solder balls in a BGA and CSP package become smaller and smaller accordingly. However, due to the limitation of the spacing S between two adjacent flux transfer pins 10, the size of the solder ball cannot be smaller than about 0.15 mm and the pitch between two adjacent solder balls cannot be smaller than about 0.3 mm, such that the development of the electronic devices is limited.

### SUMMARY OF THE INVENTION

The invention provides a flux transfer tool and a flux transfer method for improving a flux transfer process of a BGA and CSP package, so as to solve the aforesaid problems.

According to an embodiment of the invention, a flux transfer tool comprises a flux tray, a baseplate, a flux transfer head and a flexible member. The baseplate is disposed on the flux tray. The baseplate has a plurality of holes formed thereon. The flux transfer head is arranged corresponding to the flux tray and configured to move with respect to the flux tray. The flexible member is disposed on the flux transfer head. The flexible member faces the baseplate when the flux transfer head is located above the flux tray. When the holes are filled with a flux, the flux transfer head moves towards the flux tray, such that the flexible member adsorbs the flux from the holes.

According to another embodiment of the invention, a flux transfer method is performed by a flux transfer tool. The flux transfer tool comprises a flux tray, a baseplate, a flux transfer head and a flexible member. The baseplate is disposed on the flux tray. The baseplate has a plurality of holes formed thereon. The flux transfer head is arranged corresponding to the flux tray and configured to move with respect to the flux tray. The flexible member is disposed on the flux transfer head. The flux transfer method comprises steps of filling the holes with a flux; moving the flux transfer head towards the flux tray, such that the flexible member adsorbs the flux from the holes; moving the flux transfer head to a position above a substrate, wherein the substrate has a plurality of bond pads and the holes of the baseplate are arranged corresponding to the bond pads of the substrate; moving the flux transfer head towards the substrate to transfer the flux from the flexible member to the bond pads of the substrate.

As mentioned in the above, the invention utilizes the flexible member of the flux transfer head to adsorb the flux from the holes of the baseplate and then transfers the flux from the flexible member to the bond pads of the substrate by the flux transfer head. Since the holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a side view illustrating a flux transfer tool of the prior art.

FIG. 2 is a side view illustrating the flux transfer pins adhered with the flux.

FIG. 3 is a side view illustrating the flux transferred from the flux transfer pins to the bond pads of the substrate.

FIG. 4 is a side view illustrating a flux transfer tool according to an embodiment of the invention.

FIG. 5 is a side view illustrating the holes of the baseplate filled with the flux.

FIG. 6 is a side view illustrating the flux transfer head moving towards the flux tray.

FIG. 7 is a side view illustrating the flexible member adsorbing the flux from the holes.

FIG. 8 is a side view illustrating the flux transfer head moving to a position above the substrate.

FIG. 9 is a side view illustrating the flux transfer head moving towards the substrate.

FIG. 10 is a side view illustrating the flux transferred from the flexible member to the bond pads of the substrate.

FIG. 11 is a flowchart illustrating a flux transfer method according to an embodiment of the invention.

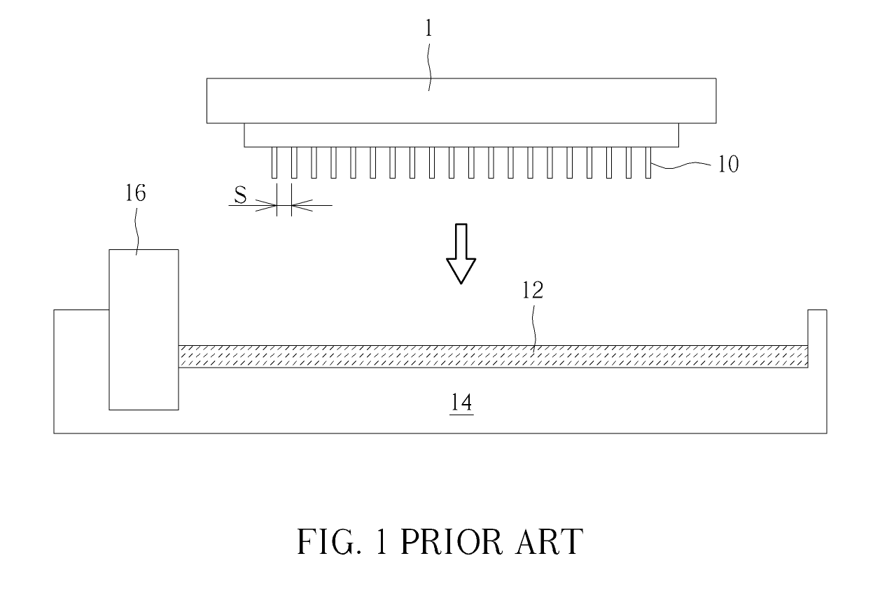

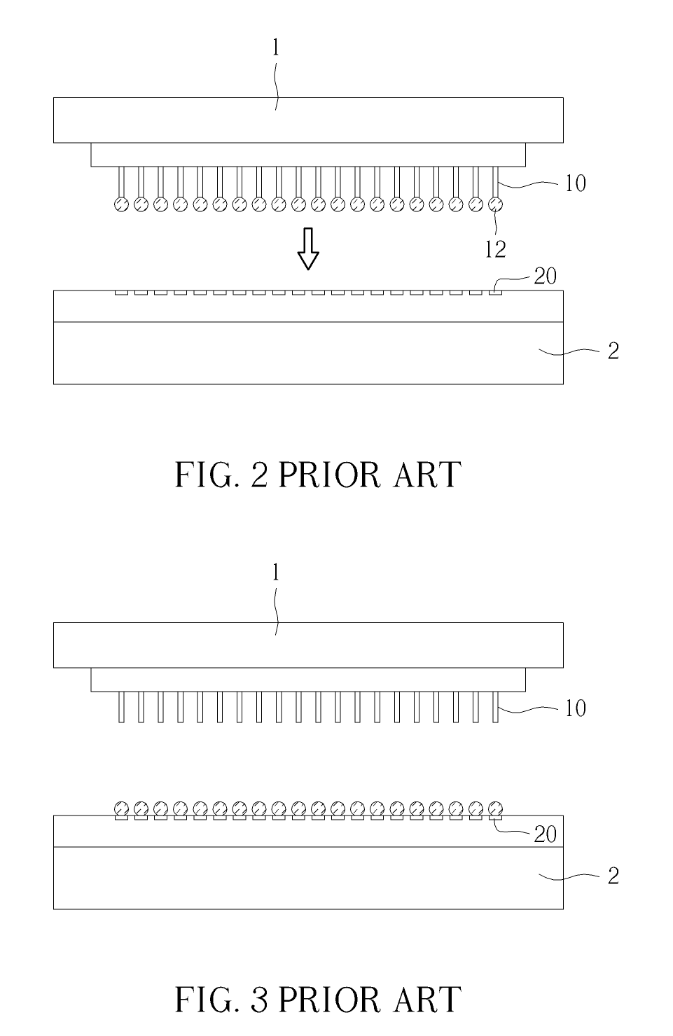

### DETAILED DESCRIPTION

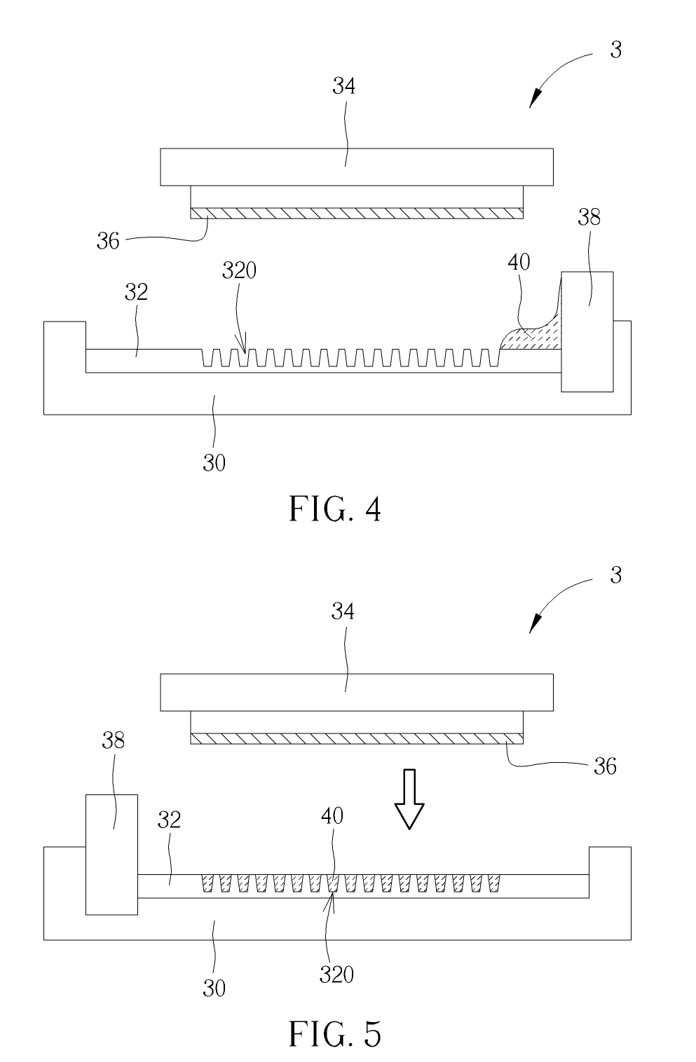

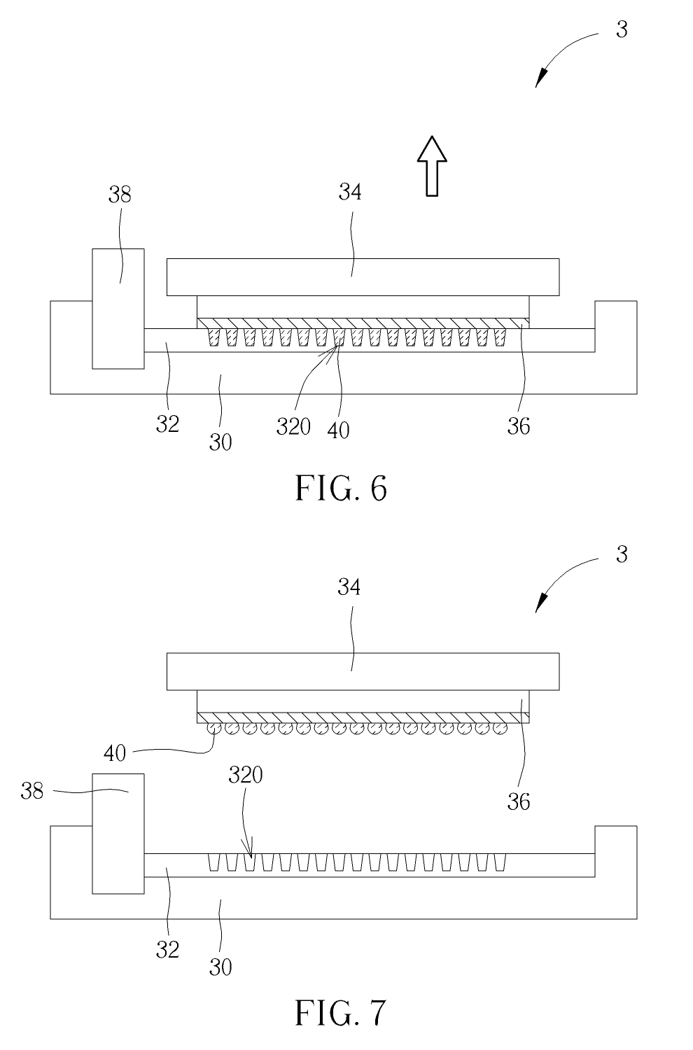

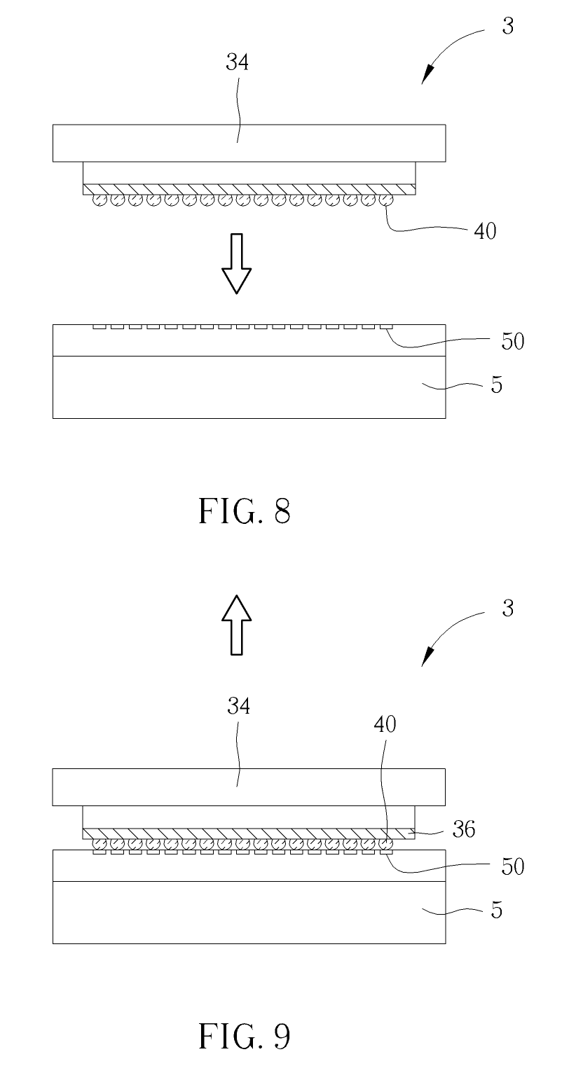

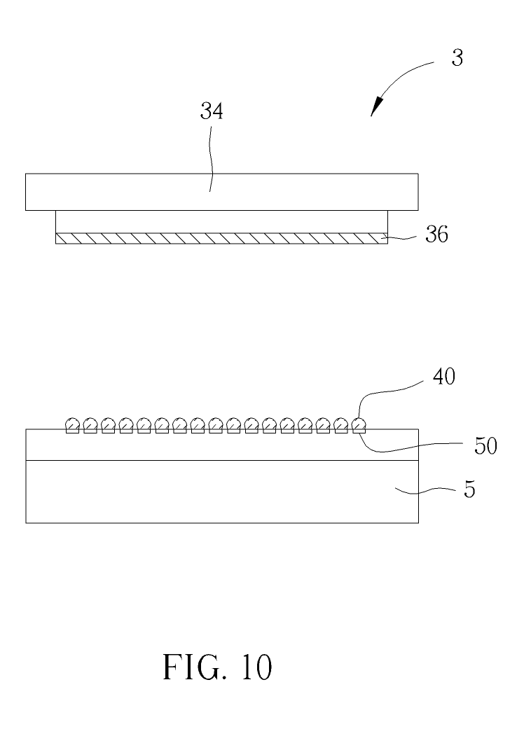

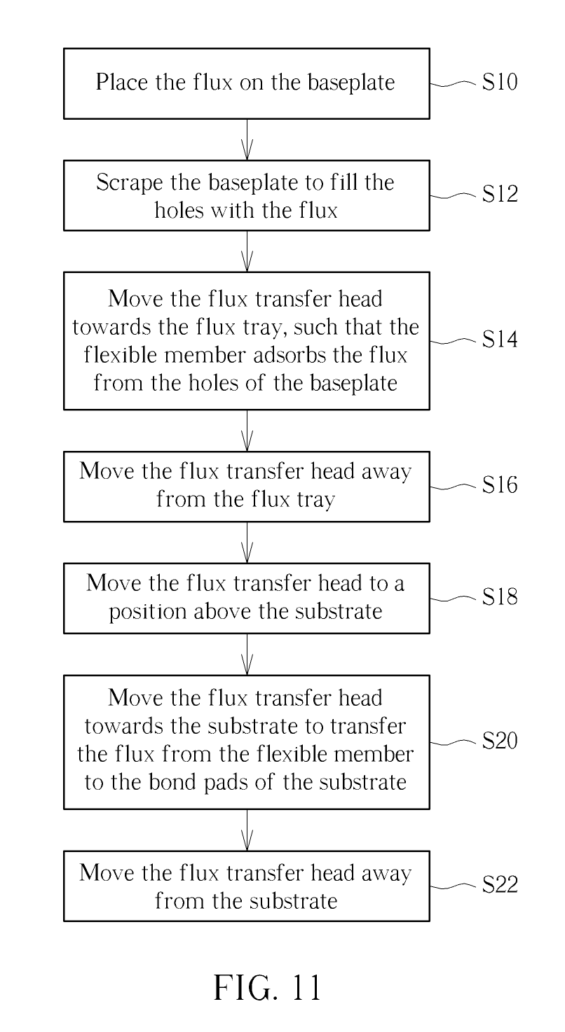

Referring to FIGS. 4 to 11, FIG. 4 is a side view illustrating a flux transfer tool 3 according to an embodiment of the invention, FIG. 5 is a side view illustrating the holes 320 of the baseplate 32 filled with the flux 40, FIG. 6 is a side view illustrating the flux transfer head 34 moving towards the flux tray 30, FIG. 7 is a side view illustrating the flexible member 36 adsorbing the flux 40 from the holes 320, FIG. 8 is a side view illustrating the flux transfer head 34 moving to a position above the substrate 5, FIG. 9 is a side view illustrating the flux transfer head 34 moving towards the substrate 5, FIG. 10 is a side view illustrating the flux 40 transferred from the flexible member 36 to the bond pads 50 of the substrate 5, and FIG. 11 is a flowchart illustrating a flux transfer method according to an embodiment of the invention.

As shown in FIGS. 4 to 10, the flux transfer tool 3 comprises a flux tray 30, a baseplate 32, a flux transfer head 34, a flexible member 36 and a scraper 38. The baseplate 32 is disposed on the flux tray 30 and the baseplate 32 has a plurality of holes 320 formed thereon. In this embodiment, the baseplate 32 may be, but not limited to, a stencil. The flux transfer head 34 is arranged corresponding to the flux tray 30 and configured to move with respect to the flux tray 30. The flexible member 36 is disposed on the flux transfer head 34, wherein the flexible member 36 faces the baseplate 32 when the flux transfer head 34 is located above the flux tray 30. In this embodiment, the flexible member 36 may be made of, but not limited to, rubber. In another embodiment, the flexible member 36 may be made of other high-density flexible materials according to practical applications. The scraper 38 is movably disposed on the flux tray 30.

As shown in FIGS. 8 to 10, the flux transfer tool 3 is used to transfer the flux 40 from the flexible member 36 of the flux transfer head 34 to a substrate 5. The substrate 5 may be an IC package or the like. The substrate 5 has a plurality of bond pads 50 and the holes 320 of the baseplate 32 are arranged corresponding to the bond pads 50 of the substrate 5.

The flux transfer method of the invention shown in FIG. 11 is performed by the flux transfer tool 3. To transfer the flux 40 from the flexible member 36 of the flux transfer head 34 to the substrate 5, first, the flux 40 is placed on the baseplate 32, as shown in FIG. 4 and step S10 in FIG. 11. When the flux 40 is placed on the baseplate 32, the scraper 38 is operated to move with respect to the baseplate 32, so as to scrape the baseplate 32 to fill the holes 320 with the flux 40, as shown in FIG. 5 and step S12 in FIG. 11.

When the holes 320 of the baseplate 32 are filled with the flux 40, the flux transfer head 34 moves towards the flux tray 30, such that the flexible member 36 contacts and adsorbs the flux 40 from the holes 320 of the baseplate 32, as shown in FIG. 6 and step S14 in FIG. 11. Then, the flux transfer head 34 moves away from the flux tray 30 and the flux 40 is adsorbed by surface tension of the flexible member 36, as shown in FIG. 7 and step S16 in FIG. 11. In this embodiment, when the flux 40 is adsorbed by the flexible member 36, a contact angle between the flux 40 and the flexible member 36 may be, but not limited to, more than 20 degrees, such that the flux 40 can be adsorbed by the flexible member 36 well. The invention can control the contact angle between the flux 40 and the flexible member 36 by the material of the flexible member 36.

Then, the flux transfer head 34 moves to a position above the substrate 5, as shown in FIG. 8 and step S18 in FIG. 11. Then, the flux transfer head 34 moves towards the substrate 5 to transfer the flux 40 from the flexible member 36 to the bond pads 50 of the substrate 5, as shown in FIG. 9 and step S20 in FIG. 11. Then, the flux transfer head 34 moves away from the substrate 5 and the flux 40 is formed on the bond pads 50 of the substrate 5, as shown in FIG. 10 and step S22 in FIG. 11.

In this embodiment, the holes 320 on the baseplate 32 can be adjusted in accordance with the size of the solder ball and the pitch between two adjacent solder balls, so the BGA and CSP package can be miniaturized according to practical demand.

As mentioned in the above, the invention utilizes the flexible member of the flux transfer head to adsorb the flux from the holes of the baseplate and then transfers the flux from the flexible member to the bond pads of the substrate by the flux transfer head. Since the holes on the baseplate can be adjusted in accordance with the size of the solder ball and the pitch between two adjacent solder balls, the BGA and CSP package can be miniaturized according to practical demand. Accordingly, the invention can improve the flux transfer process of the BGA and CSP package and save the cost of manufacturing the flux transfer pin of the prior art.

Those skilled in the art will readily observe that numerous modifications and alterations of the device and method may be made while retaining the teachings of the invention. Accordingly, the above disclosure should be construed as limited only by the metes and bounds of the appended claims.

1. A flux transfer tool comprising:
a flux tray;
a baseplate disposed on the flux tray, the baseplate having a plurality of holes formed thereon;
a flux transfer head arranged corresponding to the flux tray and configured to move with respect to the flux tray; and
a flexible member disposed on the flux transfer head, the flexible member facing the baseplate when the flux transfer head being located above the flux tray;
wherein when the holes are filled with a flux, the flux transfer head moves towards the flux tray, such that the flexible member adsorbs the flux from the holes.

2. The flux transfer tool of claim 1, further comprising a scraper movably disposed on the flux tray, wherein when the flux is placed on the baseplate, the scraper scrapes the baseplate to fill the holes with the flux.

3. The flux transfer tool of claim 1, wherein when the flux is adsorbed by the flexible member, a contact angle between the flux and the flexible member is more than 20 degrees.

4. The flux transfer tool of claim 1, wherein the flexible member is made of rubber.

5. The flux transfer tool of claim 1, wherein the holes of the baseplate are arranged corresponding to a plurality of bond pads of a substrate.

6. A flux transfer method performed by a flux transfer tool, the flux transfer tool comprising a flux tray, a baseplate, a flux transfer head and a flexible member, the baseplate being disposed on the flux tray, the baseplate having a plurality of holes formed thereon, the flux transfer head being arranged corresponding to the flux tray and configured to move with respect to the flux tray, the flexible member being disposed on the flux transfer head, the flux transfer method comprising steps of:
filling the holes with a flux;
moving the flux transfer head towards the flux tray, such that the flexible member adsorbs the flux from the holes;
moving the flux transfer head to a position above a substrate, wherein the substrate has a plurality of bond pads and the holes of the baseplate are arranged corresponding to the bond pads of the substrate; and
moving the flux transfer head towards the substrate to transfer the flux from the flexible member to the bond pads of the substrate.

7. The flux transfer method of claim 6, wherein the flux transfer tool further comprises a scraper movably disposed on the flux tray, the flux transfer method further comprises steps of:
placing the flux on the baseplate; and
moving the scraper to scrape the baseplate to fill the holes with the flux.

8. The flux transfer method of claim 6, wherein when the flux is adsorbed by the flexible member, a contact angle between the flux and the flexible member is more than 20 degrees.
